(19) United States
(12) Patent Application Publication
(10) Pub. No.: US 2013/0295725 A1
(43) Pub. Date: Nov. 7, 2013

(54) SEMICONDUCTOR PACKAGE AND METHOD OF FORMING THE SAME

(71) Applicants: Jin-Woo PARK, Seoul (KR); Seokhyun LEE, Hwaseong-si (KR)

(72) Inventors: Jin-Woo PARK, Seoul (KR); Seokhyun LEE, Hwaseong-si (KR)

(21) Appl. No.: 13/651,453

(22) Filed: Oct. 14, 2012

(30) Foreign Application Priority Data
May 3, 2012 (KR) 10-2012-0046997

(51) Int. Cl. H01L 21/56

(52) U.S. Cl. 438/124; 257/E21.502

(57) ABSTRACT

The inventive concept provides semiconductor packages and methods of forming the same. The semiconductor package includes a buffer layer covering at least one sidewall of the semiconductor chip. The buffer layer is covered by a molding layer. Thus, reliability of the semiconductor package may be improved.

### CROSS-REFERENCE TO RELATED APPLICATIONS

This U.S. non-provisional patent application claims priority under 35 U.S.C. §119 to Korean Patent Application No. 10-2012-0046997, filed on May 3, 2012, the entirety of which is incorporated by reference herein.

### BACKGROUND

The inventive concept relates to semiconductor packages and methods of forming the same.

Traditionally, smaller and more lightweight semiconductor packages with low manufacturing costs are desirable for the electronics industry. Further, many kinds of semiconductor packages have been developed to be employed in various applications. For example, a ball grid array (BGA) package may be formed by mounting a semiconductor chip on a printed circuit board (PCB), performing a molding process, and then bonding solder balls to a bottom of the PCB. The BGA package in general needs the molding process and the PCB, so that it is difficult to reduce a thickness of the BGA package.

A wafer level package (WLP) has been suggested for dealing with the above disadvantage of the BGA package. In the WLP package, a redistribution layer may be formed on a bottom of a semiconductor chip. The molding process and the PCB may not be needed in the WLP package. Thus, the WLP package may be formed using a simple process with a reduced thickness. However, since the size of the WLP package is very small, there can be other issues with WLP packages.

### SUMMARY

In some embodiments, a semiconductor package comprises a first semiconductor chip including a first surface and a second surface opposite to each other. The first semiconductor chip has a first conductive pattern and a first passivation layer covering the first surface and having an opening to expose the first conductive pattern. The semiconductor package also includes a buffer layer covering a top surface and sidewalls of the first semiconductor chip; a molding layer overlying the buffer layer; and a first redistribution layer disposed on a bottom surface of the first passivation layer. The first redistribution layer is electrically connected to the first conductive pattern.

In some embodiments, the first redistribution layer may be directly in contact with the first passivation layer.

### BRIEF DESCRIPTION OF THE DRAWINGS

The inventive concept will become more apparent in view of the attached drawings and accompanying detailed description.

FIG. 1 is a cross-sectional view illustrating a semiconductor package according to a first embodiment of the inventive concept;

FIGS. 2 and 3 are enlarged views of a portion ‘A’ of FIG. 1;

FIGS. 4 through 11 are cross-sectional views illustrating a method of forming a semiconductor package of FIG. 1;

FIG. 12 is a cross-sectional view illustrating a modified example of a semiconductor package of FIG. 1;

FIG. 13 is a cross-sectional view illustrating a semiconductor package according to a second embodiment of the inventive concept;

FIGS. 14 through 19 are cross-sectional views illustrating a method of forming a semiconductor package of FIG. 13;

FIG. 20 is a cross-sectional view illustrating a semiconductor package according to a third embodiment of the inventive concept;

FIGS. 21 through 25 are cross-sectional views illustrating a method of forming a semiconductor package of FIG. 20;

FIGS. 26 and 27 are cross-sectional views illustrating modified examples of a semiconductor package of FIG. 20;

FIG. 28 is a cross-sectional view illustrating a semiconductor package according to a fourth embodiment of the inventive concept;

FIG. 29 is a schematic view illustrating an example of package modules including semiconductor packages according to embodiments of the inventive concept;

FIG. 30 is a schematic block diagram illustrating an example of electronic devices including semiconductor packages according to embodiments of the inventive concept; and

FIG. 31 is a schematic block diagram illustrating an example of memory systems including semiconductor packages according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated, as a rectangle will, typically, have rounded or curved features. Thus, the regions illustrated in the figures are schematic in nature and their shapes are not intended to illustrate the actual shape of a region of a device and are not intended to limit the scope of example embodiments.

### First Embodiment

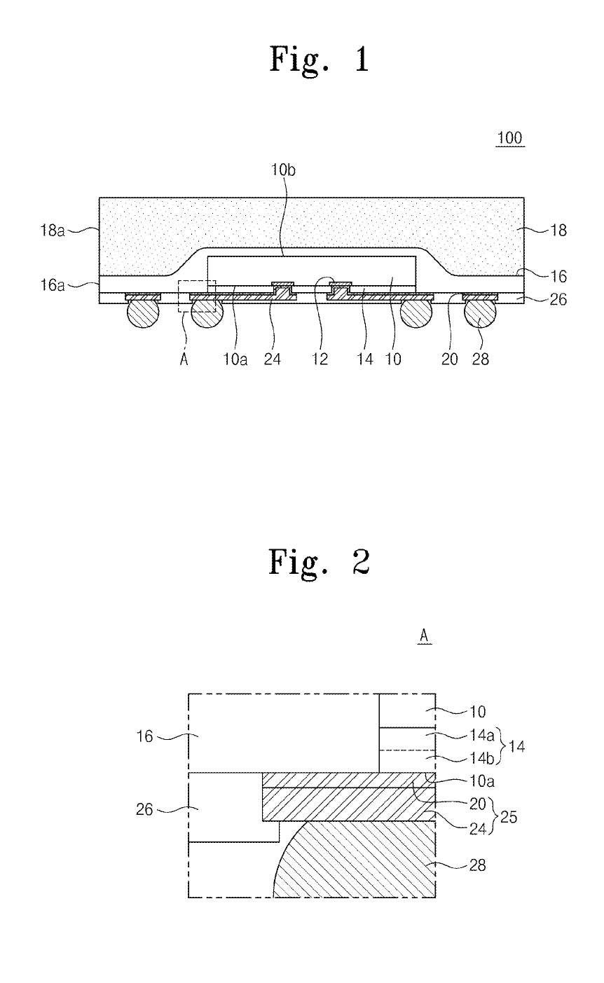

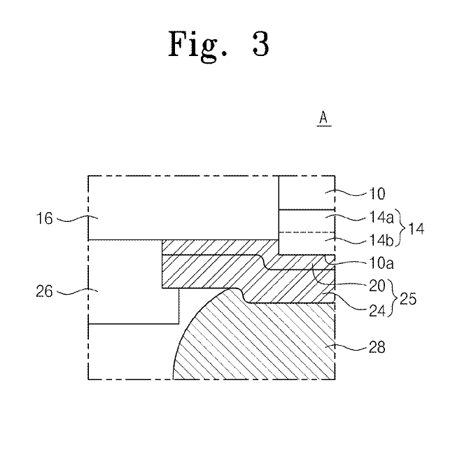

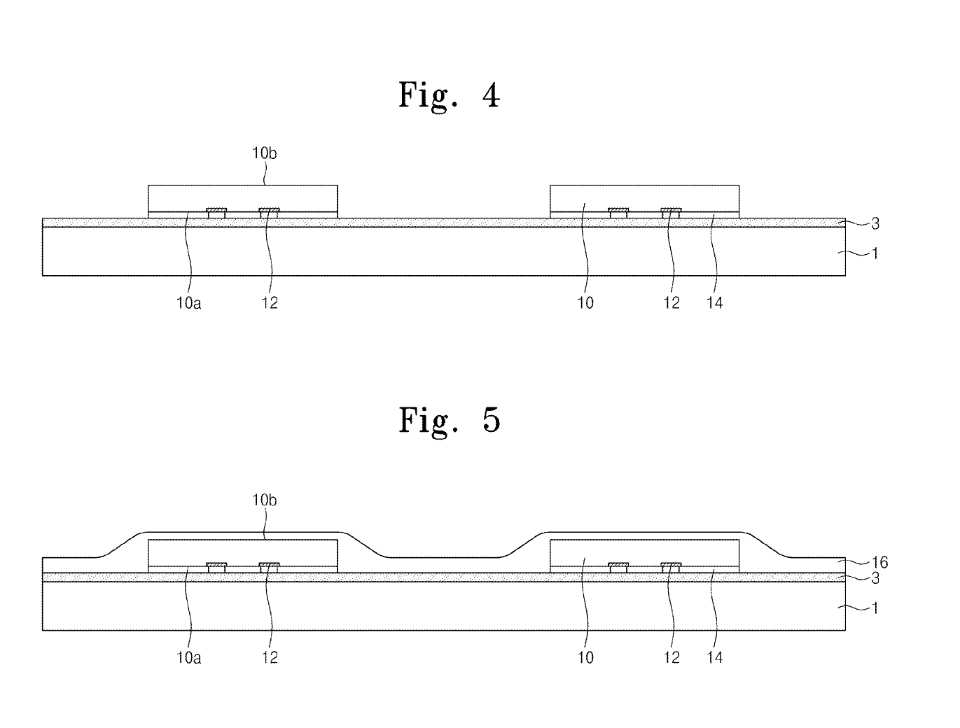

FIG. 1 is a cross-sectional view illustrating a semiconductor package according to a first embodiment of the inventive concept. FIGS. 2 and 3 are enlarged views of a portion ‘A’ of FIG. 1.

Referring to FIGS. 1, 2, and 3, a semiconductor package 100 according to a first embodiment includes a semiconductor chip 10. The semiconductor chip 10 includes a first surface 10a and a second surface 10b opposite to each other. For example, the first surface 10a may be a bottom surface of the semiconductor chip 10 and the second surface 10b may be a top surface of the semiconductor chip 10. The semiconductor chip 10 may include a conductive pad (or a bonding pad) 12 exposed at the first surface 10a. The semiconductor chip 10 may be one of various memory chips and various logic chips. A first passivation layer 14 may cover the first surface 10a of the semiconductor chip 10. For example, the first passivation layer 14 may be a double-layer of, for example, a silicon nitride layer 14a and a polyimide layer 14b. The first passivation layer 14 may also be formed of other suitable materials such as a silicon oxide-nitride layer. A buffer layer 16 may cover a sidewall and the top surface 10b of the semiconductor chip 10. A molding layer 18 may cover the buffer layer 16. A bottom surface of the buffer layer 16 may be disposed at substantially the same level as a bottom surface of the first passivation layer 14 as illustrated in FIG. 2. Alternatively, the bottom surface of the buffer layer 16 may be disposed at a level higher than the bottom surface of the first passivation layer 14 as illustrated in FIG. 3. In one embodiment, the buffer layer 16 may be disposed between the top surface 10b of the semiconductor chip 10 and the molding layer 18.

A redistribution pattern 24 may be disposed under the first passivation layer 14. The redistribution pattern 24 penetrates the first passivation layer 14 so as to be electrically connected to the conductive pad 12. The redistribution pattern 24 extends so as to be adjacent to the bottom surface of the buffer layer 16.

A seed layer pattern 20 may be disposed between the redistribution pattern 24 and the first passivation layer 14, between the redistribution pattern 24 and the buffer layer 16, and between the redistribution pattern 24 and the conductive pad 12. The redistribution pattern 24 and the seed layer pattern 20 may be formed of a metal such as copper, nickel, and/or tin.

In some embodiments, the seed layer pattern 20 and the redistribution pattern 24 may collectively form a redistribution layer 25. In this case, the redistribution layer 25 may be a double layer including a seed metal and a plating metal. In another embodiment, the redistribution layer 25 may be formed as a single layer.

In one embodiment, the redistribution layer 25 may be in contact (e.g., direct contact) with the bottom surface of the buffer layer 16. In another embodiment, the redistribution layer 25 may also be in contact (e.g., direct contact) with the first passivation layer 14.

A second passivation layer 26 may partially cover the redistribution pattern 24, and a region of the redistribution pattern 24 to which an external terminal such as a solder ball 28 is bonded (electrically coupled) may be exposed. The second passivation layer 26 may be in contact with the bottom surface of the buffer layer 16. For example, the second passivation layer 26 may be formed of a polymer layer such as a polyimide layer. The solder ball 28 is bonded to a bottom surface of the redistribution pattern 24.

In some embodiments, the second passivation layer 26 may cover the bottom surface of the first passivation layer 14, the buffer layer 16 and a portion of the redistribution layer 25.

In some embodiments, the second passivation layer 26 may include the same material as the first passivation layer 14 and the buffer layer 16.

The semiconductor package according to the first embodiment may be a so-called fan-out wafer level package (FO-WLP). In a fan-out type package, at least some of the external contact pads and/or conductor tracks electrically connecting a semiconductor chip to the external contact pads are located laterally outside of the outline of the semiconductor chip or at least intersect the outline of the semiconductor chip. Thus, in fan-out type packages, a peripherally outer part of the package of the semiconductor chip can be used for electrically bonding the package to external applications. This outer part of the package encompassing the semiconductor chip effectively enlarges the contact area of the package in relation to the footprint of the semiconductor chip.

The molding layer 18 may include an organic material such as an epoxy-based polymer layer and filler particles. Silica or alumina may be used as the filler particles. In some embodiments, the molding layer 18 may have a filler content ranging from about 85% to about 92%. The molding layer 18 may have a suitable thermal expansion coefficient and a suitable elasticity coefficient so as to suppress warpage of the entire semiconductor package 100. The suitable thermal expansion coefficient of the molding layer 18 for suppressing the warpage may be ranging from about 7 ppm/° C. to about 20 ppm/° C. Particularly, the suitable thermal expansion coefficient of the molding layer 18 may be about 7 ppm/° C. The elasticity coefficient of the molding layer 18 for suppressing the warpage may be ranging from about 20 GPa to about 25 GPa. On the other hand, a thermal expansion coefficient of the semiconductor chip 10 may be ranging from about 3 ppm/° C. to about 4 ppm/° C. The buffer layer 16 may have physical properties different from that of the molding layer 18. Such physical properties may be, among others, dielectric constant, adhesion strength, flexibility, thermal expansion coefficient and an elasticity coefficient. In one embodiment, the buffer layer 16 may be formed of a dielectric material different from a material that forms the molding layer 18.

The buffer layer 16 may relieve stress caused by differences between physical properties of the semiconductor chip 10 and the molding layer 18. For relieving stress, the buffer layer 16 may have a suitable thermal expansion coefficient and a suitable elasticity coefficient. The thermal expansion coefficient of the buffer layer 16 may be ranging from about 50 ppm/° C. to about 150 ppm/° C. Particularly, The thermal expansion coefficient of the buffer layer 16 may be ranging from about 50 ppm/° C. to about 100 ppm/° C. The elasticity coefficient of the buffer layer 16 may be ranging from about 1 GPa to about 4 GPa. Additionally, the buffer layer 16 may have photosensitivity. A photosensitive resin layer may be used as the buffer layer 16. Particularly, a photosensitive polyimide-based polymer layer, e.g., photosensitive polyimide (PSPI), may be used as the buffer layer 16. The buffer layer 16 may include the same material as the first passivation layer 14. Alternatively, the buffer layer 16 may be formed of non-photosensitive polymer materials such as non-photosensitive Polyimide.

If the buffer layer 16 of the inventive concept does not exist, various problems relative to reliability of a semiconductor package may occur by the difference between the physical properties of the semiconductor chip 10 and the molding layer 18. For example, stress may occur between the molding layer 18 and the semiconductor chip 10 due to differences between the physical properties of the semiconductor chip 10 and the molding layer 18. The stress may concentrate on the sidewall of the semiconductor chip 10. Thus, a space between the molding layer 18 and the sidewall of the semiconductor chip 10 may be widened or the semiconductor package may be warped. Additionally, a board level reliability may be deteriorated by the warpage of the semiconductor package, so that a joint crack may occur at the solder ball bonded to a board substrate. However, according to some embodiments of the inventive concept, the buffer layer 16 is disposed between the molding layer 18 and at least one sidewall of the semiconductor chip 10 so as to relieve the stress caused by the difference between the physical properties of the semiconductor chip 10 and the molding layer 18. Thus, it is possible to resolve the problems caused by the stress.

According to one embodiment, the molding layer 18 may be spaced apart from the first passivation layer 14, for example, by the buffer layer 16. In another embodiment, the second passivation layer 26 may be spaced apart from the molding layer 18, for example, by the buffer layer 16.

In some embodiments, a sidewall 16a of the buffer layer 16 and a sidewall 18a of the molding layer 18 are substantially vertically aligned with each other as shown in FIG. 1. As a result, the sidewall 16a of the buffer layer and the sidewall 18a of the molding layer 18 form an external sidewall of the package 100.

FIGS. 4 through 11 are cross-sectional views illustrating a method of forming a semiconductor package of FIG. 1.

Referring to FIG. 4, semiconductor chips 10 are bonded to a carrier 1 with an adhesion layer 3 therebetween. The carrier 1 may be formed of at least one of various materials such as a glass, a plastic, and a metal. The adhesion layer 3 may be a double-sided tape or an adhesive. If the adhesion layer 3 is the double-sided tape, the adhesion layer 3 may be bonded to the carrier 1 by a lamination process using vacuum. If the adhesion layer 3 is the adhesive, the adhesion layer 3 may be formed on the carrier 1 by an ink-jetting process, a printing process, and/or a coating process. Each of the semiconductor chips 10 includes a first surface 10a and a second surface 10b opposite to each other and a conductive pad 12. A first passivation layer 14 covers the first surface 10a. The first passivation layer 14 may have an opening 13 that exposes a portion of the conductive pad 12. The first passivation layer 14 may be in contact with the adhesion layer 3.

Referring to FIG. 5, a buffer layer 16 may be formed on the carrier 1 to which the semiconductor chips 10 are bonded. The buffer layer 16 covers the semiconductor chips 10 and the adhesion layer 3. The buffer layer 16 may be formed on the semiconductor chips 10 and the adhesion layer 3 by a coating process. For example, the buffer layer 16 may be formed of a polyimide-based polymer layer. The buffer layer 16 may be formed under an atmospheric pressure.

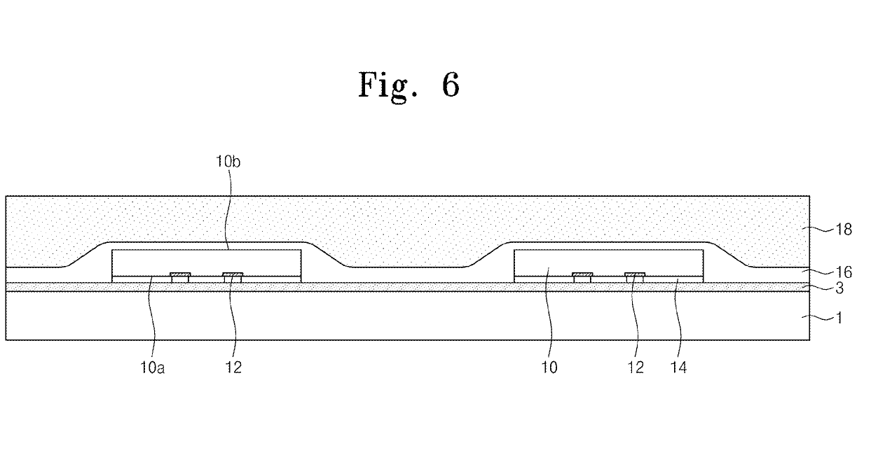

Referring to FIG. 6, a molding layer 18 is formed on the buffer layer 16. For forming the molding layer 18, the carrier 1 may be inserted in a molding layer-mold frame and then a molding layer solution may be injected into the molding layer-mold frame from the top. For reducing the formation of a void in the molding layer 18, a vacuum or decompression may be provided to a region of the molding layer-mold frame opposite to the region through which the molding layer solution is injected.

At this time, without the presence of the buffer layer 16, stress may be induced on a top surface of the semiconductor chip 10 by the injection of the molding layer solution. Additionally, the molding layer solution may invade an area beneath the bottom surface 10a of the semiconductor chip 10. Thus, the conductive pad 12 may be contaminated, the conductive pad 12 may be covered by the molding layer, or it may be possible to cause a swimming problem wherein an entire semiconductor chip is surrounded by the molding layer 18. Moreover, the semiconductor chip may be distorted or rotated by flowing of the molding layer solution during the process of forming the molding layer 18. However, according to some embodiments of the inventive concept, the molding layer 18 is formed after the buffer layer 16 is formed. Thus, the molding layer 18 does not encroach upon the bottom surface 10a of the semiconductor chip 10. Additionally, it is possible to reduce or prevent the swimming problem and/or the rotation problem.

Furthermore, since the process forming the buffer layer 16 is performed under atmospheric pressure, it is possible to substantially reduce the swimming problem and/or the rotation problem. Thus, it may not be necessary to deeply press or fix the semiconductor chip 10 into the adhesion layer 3. As a result, a height difference between a bottom surface of the buffer layer 16 and a bottom surface of the first passivation layer 14 may not occur or may be relatively small. Thus, a subsequent redistribution pattern may be formed directly on the bottom surfaces of the buffer layer 16 and the first passivation layer 14. Therefore, additional insulating layer formation process and etching process may not be required. In detail, in the prior art, an insulating layer such as PSPI was typically formed over a molding layer and a semiconductor chip with a passivation layer before forming a redistribution layer thereon. However, with some embodiments of the present application, such an additional process step can be skipped and the redistribution layer can be directly formed on the passivation layer, which can significantly lower the manufacturing costs and simplify the overall assembly process.

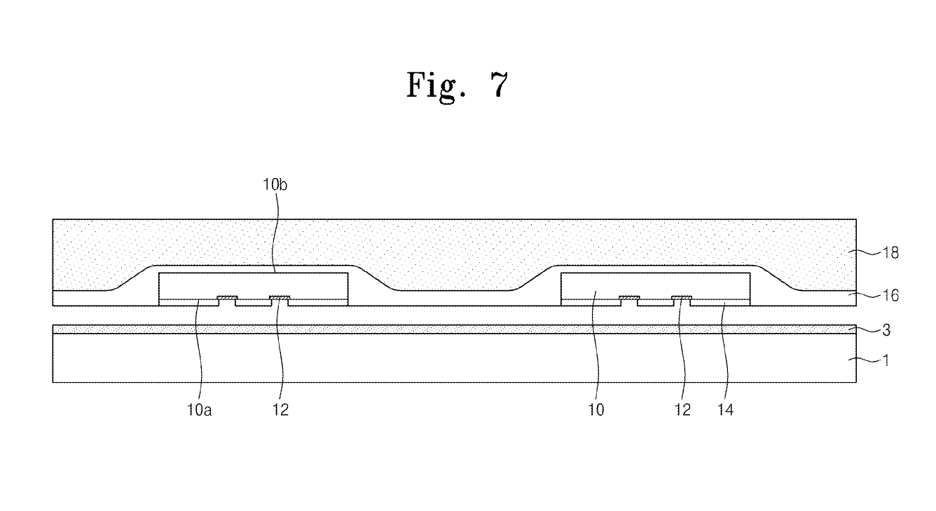

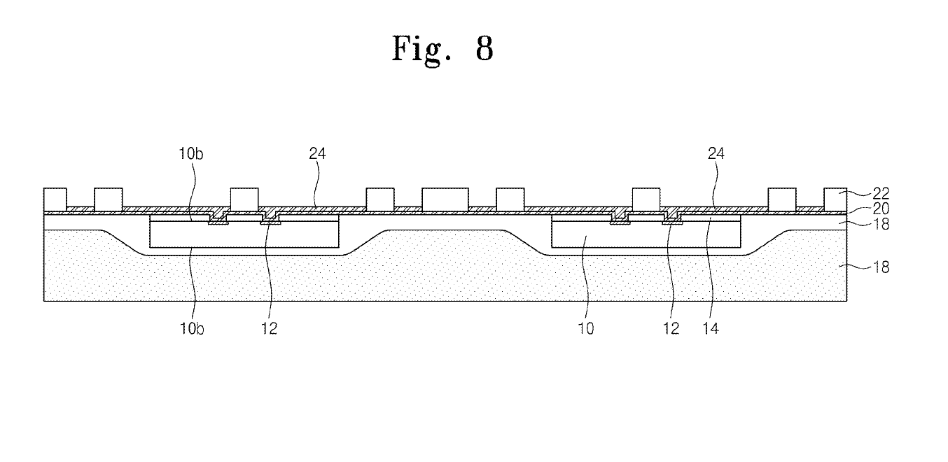

Referring to FIG. 7, the carrier 1 is separated from the semiconductor chip 10. If the adhesion layer 3 is the double-sided tape, a heat of, for example, about 170° C. or more may be supplied to the double-sided tape. Thus, the double-sided tape may lose an adhesive strength, so that it may be separated from the carrier 1. Alternatively, if the carrier 1 is formed of a glass, ultraviolet rays may be irradiated to a backside of the carrier 1, such that the double-sided tape may be hardened to lose the adhesive strength. Thus, the adhesion layer 3 may be separated from the carrier 1. In other embodiments, the adhesion layer 3 may be dissolved using chemicals so as to be removed. Thus, the bottom surfaces of the first passivation layer 14 and the buffer layer 16 are exposed. Referring to FIG. 8, the semiconductor chip 10 separated from the carrier 1 is turned upside down, so that the first surface 10a faces upwardly.

A seed layer pattern 20 may then be formed on top surfaces of the first passivation layer 14 and the buffer layer 16 of the semiconductor chip 10. The seed layer pattern 20 may be formed by a deposition process.

In some embodiments, the seed layer pattern 20 may be formed using a soft-lithography process selected from the group consisting of stencil printing process, a screen printing process, an ink-jet printing process, an imprinting process, an offset printing process.

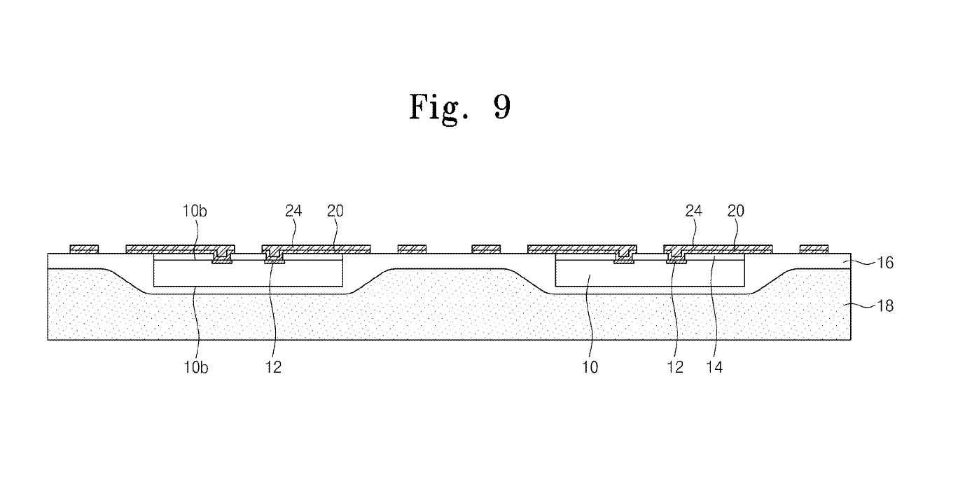

The seed layer pattern 20 may be in contact with the conductive pad 12. The seed layer pattern 20 may be formed of a metal such as copper, nickel, and/or tin. Photoresist patterns 22 defining shapes of the redistribution patterns may be formed on the seed layer 20. The photoresist patterns 22 may be formed using a photolithography process. The redistribution patterns 24 are formed on exposed portions of the seed layer 20 that are not covered by the photoresist patterns 22, for example, by a plating process. Referring to FIG. 9, the photoresist patterns 22 may be removed to expose the seed layer 20 under the photoresist patterns 22. And then the exposed portions of the seed layer 20 that are not covered by the redistribution patterns 24 are removed using the redistribution patterns 24 as etch masks to expose the first passivation layer 14 and the buffer layer 16.

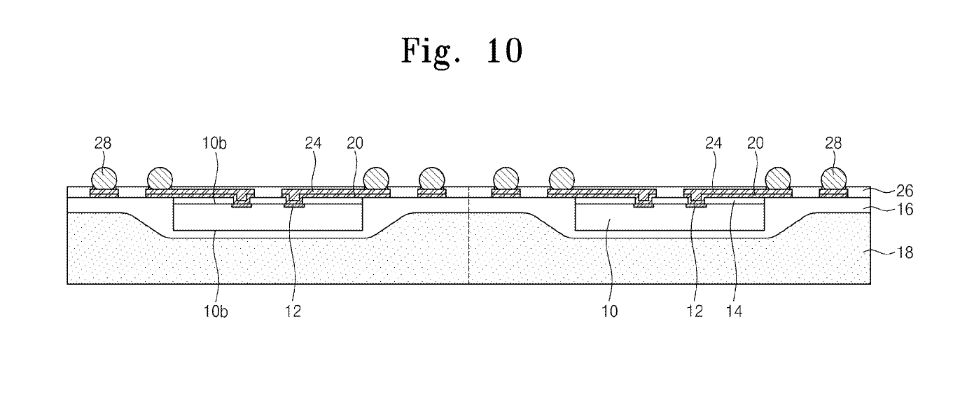

Referring to FIG. 10, a second passivation layer 26 is formed to cover portions of the redistribution patterns 24 and the buffer layer 16 and the first passivation layer 14 between the redistribution patterns 24. The second passivation layer 26 may be formed of a polyimide-based material. Solder balls 28 are bonded to exposed portions of the redistribution patterns 24 which are not covered by the second passivation layer 26.

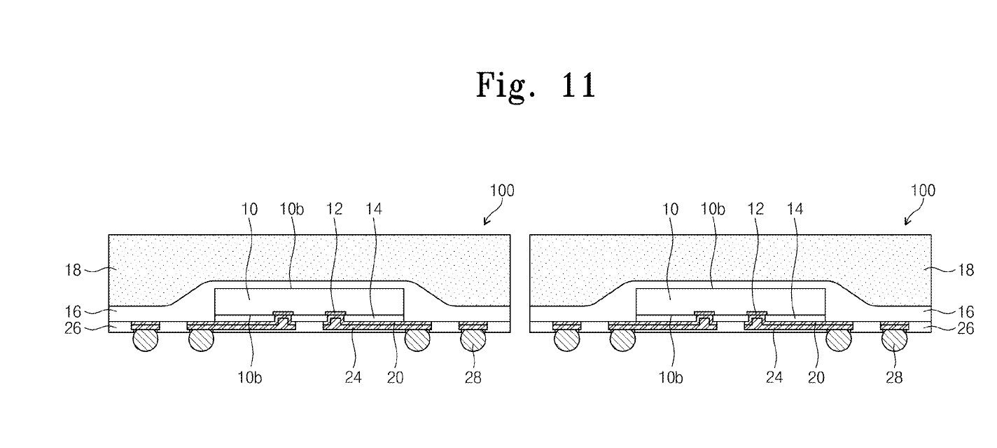

Referring to FIG. 11, a singulation process may be performed to cut the second passivation layer 26, the buffer layer 16, and the molding layer 18. Thus, unit semiconductor packages 100 are separated from each other. As a result, the semiconductor package 100 of FIG. 1 may be manufactured.

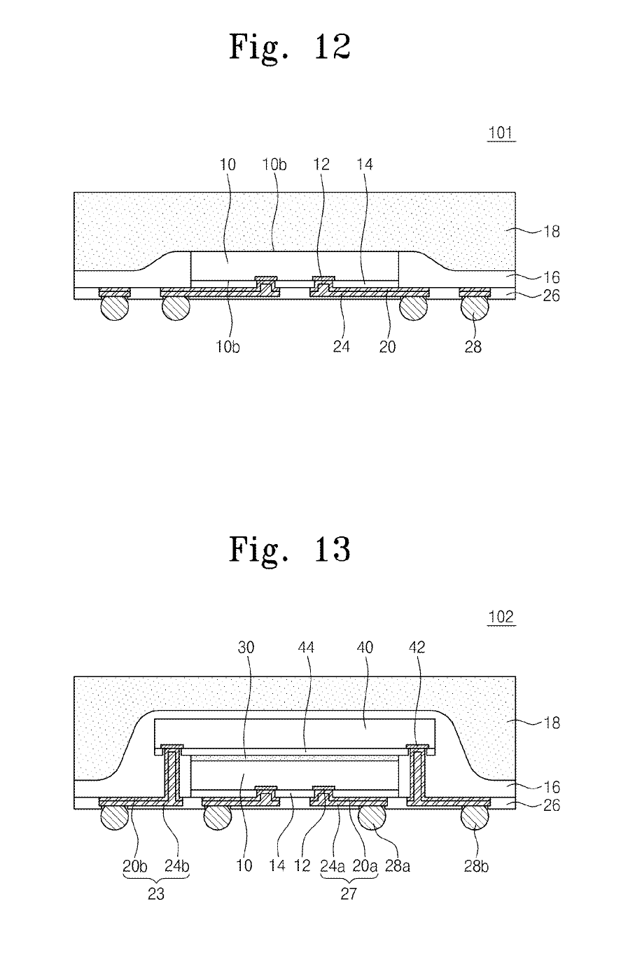

FIG. 12 is a cross-sectional view illustrating a modified example of a semiconductor package of FIG. 1.

Referring to FIG. 12, in a semiconductor package 101 according to the present modified example, a buffer layer 18 may cover substantially the entire sidewall of the semiconductor chip 10 but may not cover the top surface 10b of the semiconductor chip 10. Thus, the top surface 10b of the semiconductor chip 10 may be in contact with the molding layer 18. Other elements of the semiconductor package 101 may be the same as the corresponding elements of the semiconductor package 100 of FIG. 1.

A method of forming the semiconductor package 101 of FIG. 12 will be described. After the buffer layer 16 is formed to cover the sidewall and the top surface 10b of the semiconductor chip 10, the buffer layer 16 on the top surface 10b may be removed to expose the top surface 10b of the semiconductor chip 10. Removing the buffer layer 106 on the top surface 10b may be performed by a selective exposure process and a development process. Alternatively, removing the buffer layer 106 on the top surface 10b may be performed by a planarization process such as an etching process. Subsequent processes may be performed as described with reference to FIGS. 6 to 11.

### Second Embodiment

FIG. 13 is a cross-sectional view illustrating a semiconductor package according to a second embodiment of the inventive concept. A semiconductor package 102 according to the present embodiment has a fan-out wafer level package structure including a plurality of semiconductor chips sequentially stacked.

Referring to FIG. 13, the semiconductor package 102 according to the present embodiment includes a first semiconductor chip 10 and a second semiconductor chip 40 stacked on the first semiconductor chip 10. A second adhesion layer 30 may be disposed between the first and second semiconductor chips 10 and 40. The first and second semiconductor chips 10 may be adhered and fixed to each other by the second adhesion layer 30. The second adhesion layer 30 may be a double-sided tape or an adhesive. A first conductive pad 12 may be exposed at a bottom surface of the first semiconductor chip 10. The first conductive pad 12 may be covered by a first passivation layer 14. A second conductive pad 42 may be exposed at a bottom surface of the second semiconductor chip 40. The second conductive pad 42 may be covered by a second passivation layer 44. The first passivation layer 14 may be formed the same material as the second passivation layer 44. The second conductive pad 42 may not overlap the first semiconductor chip 10. A width of the second semiconductor chip 40 may be greater than a width of the first semiconductor chip 10. In one embodiment, a buffer layer 16 may cover a bottom surface and at least one sidewall of the second semiconductor chip 40. In another embodiment, the buffer layer 16 may cover a sidewall, a top surface, a portion of the bottom surface of the second semiconductor chip 40 and a sidewall of the first semiconductor chip 10. A molding layer 18 may be disposed on the buffer layer 16.

A first redistribution pattern 24a may be disposed on a bottom surface of the first passivation layer 14 and penetrate the first passivation layer 14 so as to be electrically connected to the first conductive pattern 12. A second redistribution pattern 24b may be disposed on a bottom surface of the buffer layer 16 and penetrate the buffer layer 16 so as to be electrically connected to the second conductive pad 42. A third passivation layer 26 covers portions of the redistribution patterns 24a and 24b and portions of the buffer layer 16 and the first passivation layer 14. A first seed layer 20a is disposed between the first redistribution pattern 24a and the first passivation layer 14 and between the first redistribution pattern 24a and the first conductive pad 12. The first seed layer 20a and the first redistribution pattern 24a may also be collectively called a first redistribution layer 23. A second seed layer 20b is disposed between the second redistribution pattern 24b and the buffer layer 16 and between the second redistribution pattern 24b and the second conductive pad 42. The second seed layer 20b and the second redistribution pattern 24b may be collectively called a second redistribution layer 27. As in the first embodiment, the first and second seed layers 20a, 20b may be formed using a soft-lithography process selected from the group consisting of stencil printing process, a screen printing process, an ink-jet printing process, an imprinting process, an offset printing process. Also, although not illustrated, the first and second redistribution layers 23, 27 may instead be formed as a single layer, not a double layer.

A first solder ball 28a may be bonded to the exposed first redistribution pattern 24a not covered by the third passivation layer 26 and a second solder ball 28b may be bonded to the exposed second redistribution pattern 24b not covered by the third passivation layer 26.

Other elements of the semiconductor package 102 may be the same as/similar to corresponding elements of the semiconductor package in the first embodiment.

In the present embodiment, the number of the stacked semiconductor chips may be two. However, the inventive concept is not limited thereto. In other embodiments, the number of the stacked semiconductor chips may be three or more.

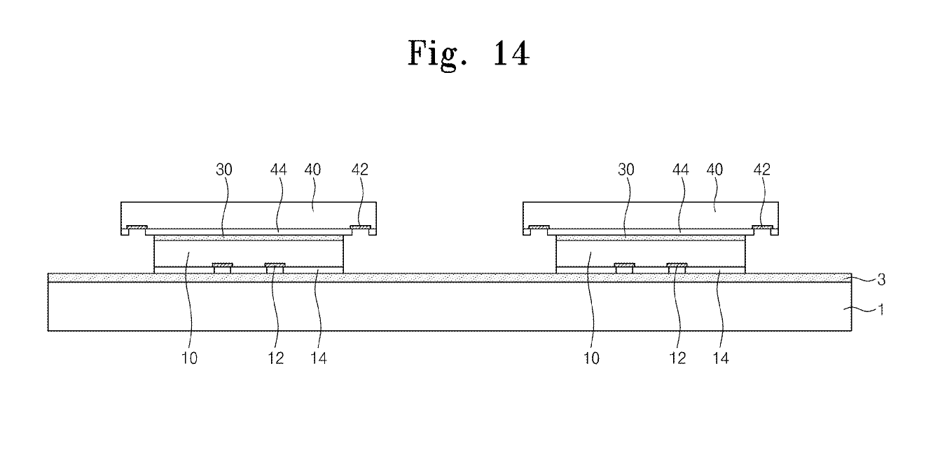

FIGS. 14 through 19 are cross-sectional views illustrating a method of forming a semiconductor package of FIG. 13.

Referring to FIG. 14, a first adhesion layer 3 is formed on a carrier 1. A first semiconductor chip 10 may be adhered on the first adhesion layer 3. A second adhesion layer 30 may be formed on a top surface of the first semiconductor chip 10 and then a second semiconductor chip 40 is adhered on the second adhesion layer 30. A first conductive pad 12 is disposed at a bottom surface of the first semiconductor chip 10 and is covered by a first passivation layer 14. A second conductive pad 42 may be disposed at a bottom surface of the second semiconductor chip 40 and is covered by a second passivation layer 44. When the second semiconductor chip 40 is adhered on second adhesion layer 30, the second conductive pad 42 does not overlap the first semiconductor chip 10, and is therefore exposed.

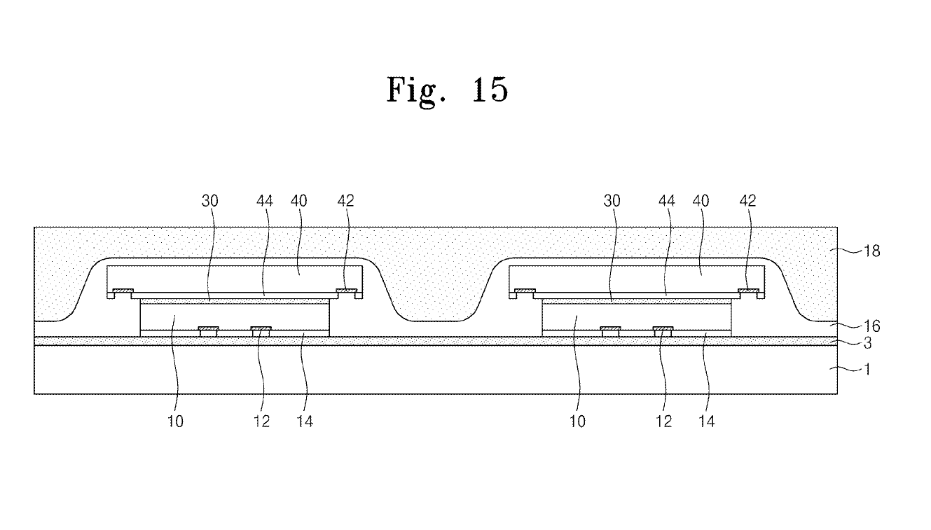

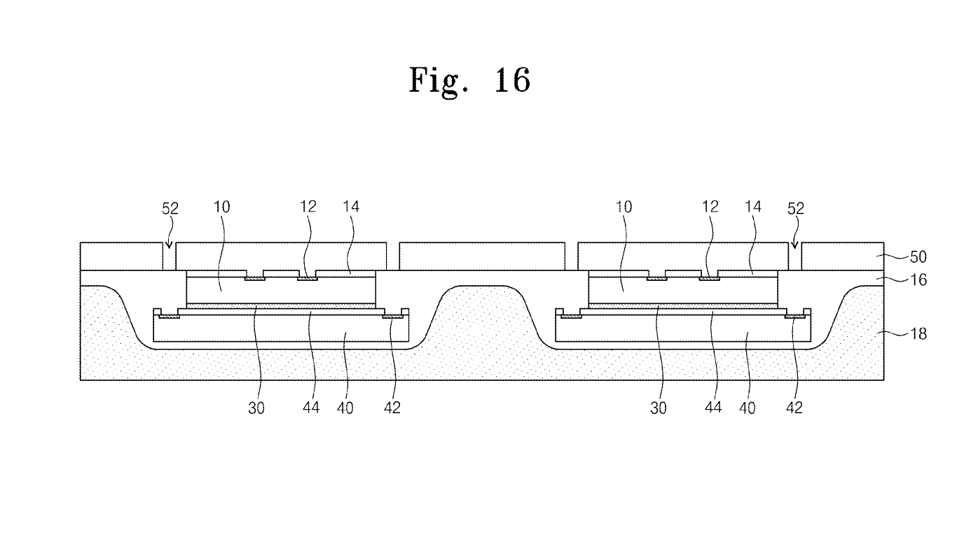

Referring to FIG. 15, a buffer layer 16 is formed on the second semiconductor chip 40. The buffer layer 16 covers a sidewall, a top surface, a portion of a bottom surface of the second semiconductor chip 40 and a sidewall of the first semiconductor chip 10. As described in the first embodiment, the buffer layer 16 may be formed by coating, for example, a photosensitive resin solution and hardening the coated photosensitive resin solution. Alternatively, according to an aspect of the present application, a non-photosensitive resin solution may be used to form the buffer layer 16. In this case, a photoresist layer may be formed over the hardened non-photosensitive resin for the patterning thereof. This aspect of the present application can be applied to other embodiments discussed in the present application. After the buffer layer 16 is formed, a molding layer 18 is formed on the buffer layer 16.

Referring to FIG. 16, the carrier 1 is separated from the first semiconductor chip 10. If the first adhesion layer 3 is the double-sided tape, a heat of, for example, about 170° C. or more may be supplied to the double-sided tape. Thus, the double-sided tape may lose an adhesive strength, so that the first adhesion layer 3 may be separated from the carrier 1. At this time, hardening temperatures of the first and second adhesion layers 3 and 30 may be different from each other. As a result the second adhesion layer 30 may not be separated from the first and second semiconductor chips 10 and 40 when the first adhesion layer 10 is separated from the carrier 1.

In other embodiments, if the carrier 1 is formed of a glass, ultraviolet rays may be irradiated to a backside of the carrier 1, such that the double-sided tape may be hardened to lose the adhesive strength. Thus, the first adhesion layer 3 may be separated from the carrier 1.

In still other embodiments, the first adhesion layer 3 may be dissolved using chemicals so as to be removed. As a result, bottom surfaces of the first passivation layer 14 and the buffer layer 16 are exposed. At this time, the adhesive strength of the second adhesion layer 30 may be maintained. The first and second semiconductor chips 10 and 40 separated from the carrier 1 may be turned over. And then a mask pattern 50 having openings 52 is formed on top surfaces of the first passivation layer 14 and the buffer layer 16 of the overturned first and second semiconductor chips 10 and 40. The mask pattern 50 may be formed of a material having an etch selectivity with respect to the buffer layer 16. For example, the mask pattern 50 may be formed of at least one of a spin on hard mask (SOH) layer, an amorphous carbon layer (ACL), a silicon nitride layer, a silicon oxide layer, a silicon oxynitride layer, a metal oxide layer, and a photoresist. The opening 52 may be vertically overlapped with the second conductive pad 42.

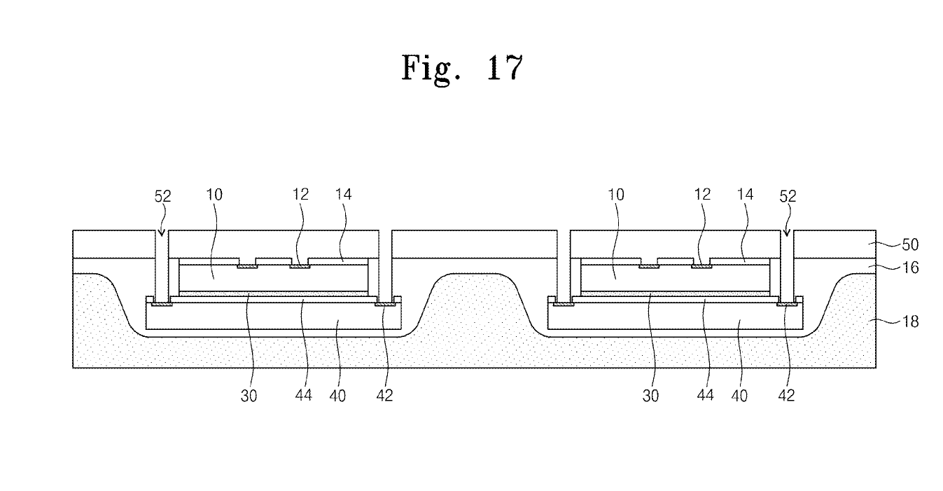

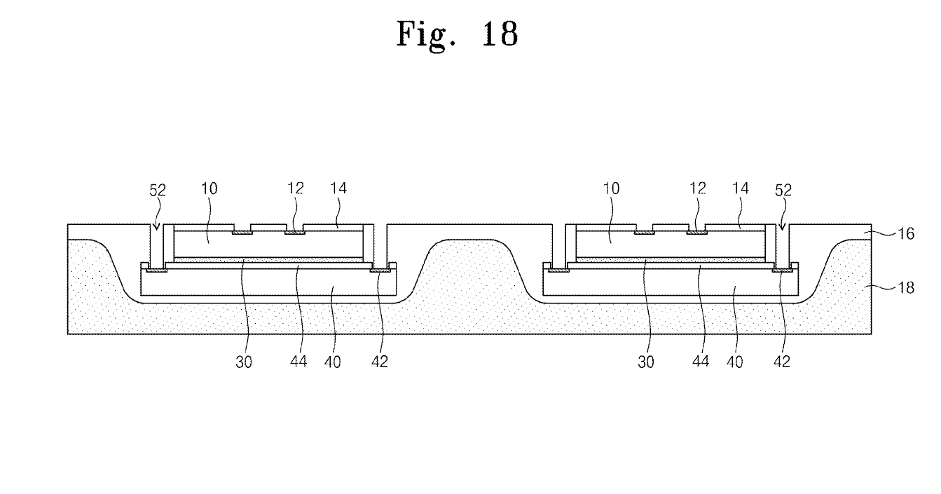

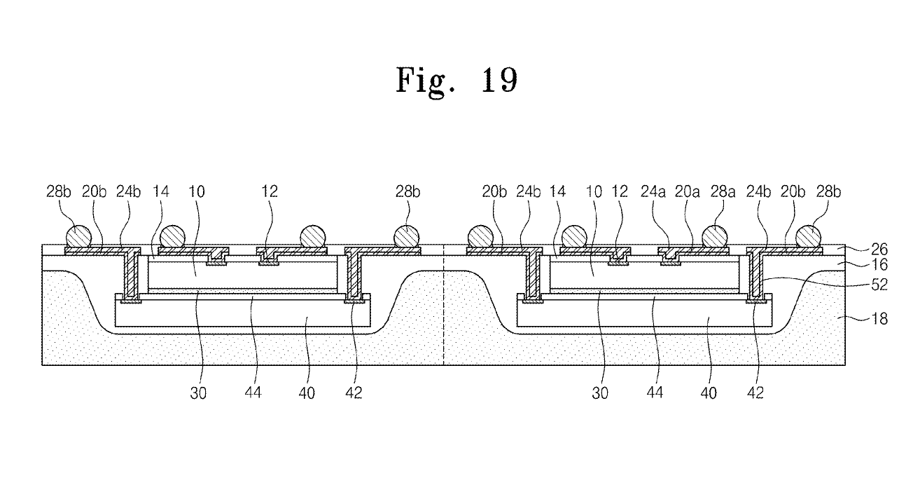

Referring to FIGS. 17 and 18, the buffer layer 16 is etched using the mask pattern 50 as an etch mask to expose a portion of the second conductive pad 42. Then, the mask pattern 16 may be etched to expose the top surfaces of the buffer layer 16 and the first passivation layer 14. Thus, the opening 52 may be extended to the buffer layer 16, so that the opening 52 may also be formed in the buffer layer 16.

Referring to FIG. 19, as described with reference to FIGS. 8 and 9, a seed layer (not shown) may be conformally formed, a photoresist pattern (not shown) may be formed on the seed layer, and then redistribution patterns 24a and 24b are selectively formed by a plating process using the selectively exposed seed layer. Next, the photoresist pattern (now shown) and the seed layer (not shown) under the photoresist pattern may be removed to form seed layer patterns 20a and 20b. A third passivation layer 26 is formed to cover portions of the redistribution patterns 24a and 24b and the buffer layer 16 and the first passivation layer 14 between the redistribution patterns 24a and 24b. The third passivation layer 26 may be formed of a polyimide-based material. Solder balls 28a and 28b may be mounted on the exposed redistribution patterns 24a and 24b not covered by the third passivation layer 26.

Subsequently, a singulation process may be performed to cut the third passivation layer 26, the buffer layer 16, and the molding layer 18, so that unit semiconductor packages 102 are separated from each other. Thus, the semiconductor package 102 of FIG. 13 may be manufactured.

### Third Embodiment

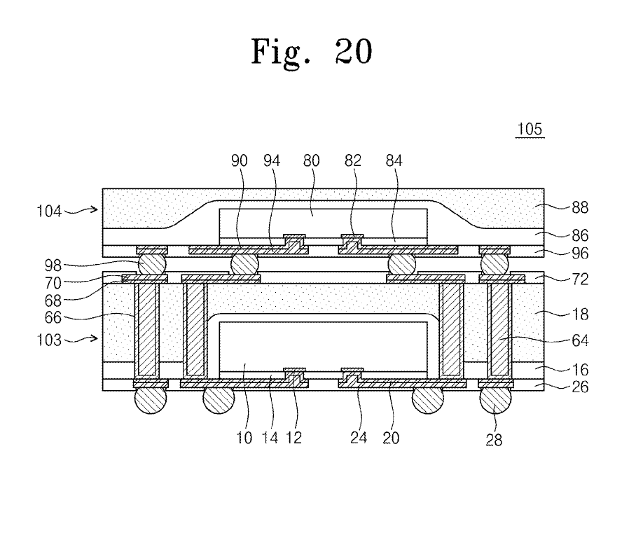

FIG. 20 is a cross-sectional view illustrating a semiconductor package according to a third embodiment of the inventive concept. A semiconductor package 105 according to the third embodiment has a package-on-package structure including stacked fan-out wafer level packages.

Referring to FIG. 20, the semiconductor package 105 according to the third embodiment includes a first semiconductor package 103 and a second semiconductor package 104 mounted on the first semiconductor package 103.

The first semiconductor package 103 includes a first semiconductor chip 10. First conductive pads 12 are disposed at a bottom surface of the first semiconductor chip 10 and are covered by a first passivation layer 14. A first buffer layer 16 may cover a sidewall and/or a top surface of the first semiconductor chip 10. First redistribution patterns 24 may be disposed adjacent a bottom surface of the first passivation layer 14 and a bottom surface of the first buffer layer 16. The first redistribution patterns 24 are electrically connected to the first conductive pads 12. A first seed layer pattern 20 may be disposed between the first redistribution pattern 24 and the first conductive pad 12, between the first redistribution pattern 24 and the first passivation layer 14, and between the first redistribution pattern 24 and the first buffer layer 16. As in the first embodiment, the first redistribution pattern 24 and the first seed layer pattern 20 may collectively form a first redistribution layer 25. Also, the first redistribution layer 25 may be formed as a single layer.

A second passivation layer 26 may cover portions of the first redistribution patterns 24, portions of the first buffer layer 16 and the first passivation layer 14. First solder balls 28 are bonded to the exposed portions of the first redistribution patterns 24 which are not covered by the second passivation layer 26. A first molding layer 18 is disposed on the first buffer layer 16.

A through-via 64 successively penetrates the first molding layer 18 and the buffer layer 16 so as to be electrically connected to the first redistribution pattern 24. A through-seed layer pattern 66 may be disposed between the through-via 64 and the first molding layer 18, between the through-via 64 and the first buffer layer 16, and between the through-via 64 and the first seed layer pattern 20. Second redistribution patterns 70 are disposed on a top surface of the molding layer 18. The second redistribution pattern 70 is electrically connected to the through-via 64.

A second seed layer pattern 68 may be disposed between the second redistribution pattern 70 and the molding layer 18 and between the second redistribution pattern 70 and the through-via 64.

A third passivation layer 72 may cover a portion of the second redistribution pattern 70 and the molding layer 18. The third passivation layer 72 may have an opening 75 that exposes a portion of the second redistribution pattern 70.

The second semiconductor package 104 includes a second semiconductor chip 80. Second conductive pads 82 are disposed at a bottom surface of the second semiconductor chip 80 and are covered by a fourth passivation layer 84. A second buffer layer 86 covers a sidewall and a top surface of the second semiconductor chip 80. In another embodiment, the second buffer layer 86 may only cover a sidewall of the second semiconductor chip 80 (not shown). A second molding layer 88 covers the second buffer layer 86. Third redistribution patterns 94 are disposed adjacent a bottom surface of the fourth passivation layer 84 and a bottom surface of the second buffer layer 86. The third redistribution patterns 94 are electrically connected to the second conductive pads 82.

A third seed layer pattern 90 may be disposed between the third redistribution pattern 94 and the second conductive pad 82, between the third redistribution pattern 94 and the fourth passivation layer 84, and between the third redistribution pattern 94 and the second buffer layer 86.

A fifth passivation layer 96 may cover portions of the third redistribution patterns 94 and portions of the second buffer layer 86 and the fourth passivation layer 84. The fifth passivation layer 96 exposes portions of the third redistribution patterns 94.

A second solder ball 98 may be disposed between the third redistribution pattern 94 and the second redistribution pattern 70 and electrically interconnects the third and second redistribution patterns 94 and 70.

The first and fourth passivation layers 14 and 96 of FIG. 20 may correspond to the first passivation layer 14 of the first embodiment of FIG. 1. For example, the first and fourth passivation layers 14 and 96 of FIG. 20 may be formed of the same material as the first passivation layer 14 of the first embodiment of FIG. 1. The second, third, and fifth passivation layers 26, 72, and 96 of FIG. 20 may correspond to and be formed of the same material as the second passivation layer 26 of the first embodiment of FIG. 1. The first to third redistribution patterns 24, 70, and 94, the seed layer patterns 20, 66, 68, and 90, and the through-via 64 may be formed of a metal such as copper, nickel, and/or tin.

The first and second buffer layers 16 and 86 may correspond to the buffer layer 16 of the first embodiment of FIG. 1. The first and second molding layers 18 and 88 may correspond to the molding layer 18 of the first embodiment of FIG. 1.

The first semiconductor chip 10 and the second semiconductor package 80 may be of the same kind, or the first semiconductor chip 10 may be of the different kind from the second semiconductor chip 80. In some embodiments, the kinds of the first and second semiconductor chips 10 and 80 may be different from each other. For example, the first semiconductor chip 10 may be a logic chip and the second semiconductor chip 80 may be a memory chip. Other elements of the semiconductor package 105 may be the same as/similar to the corresponding elements of the semiconductor package of the first embodiment.

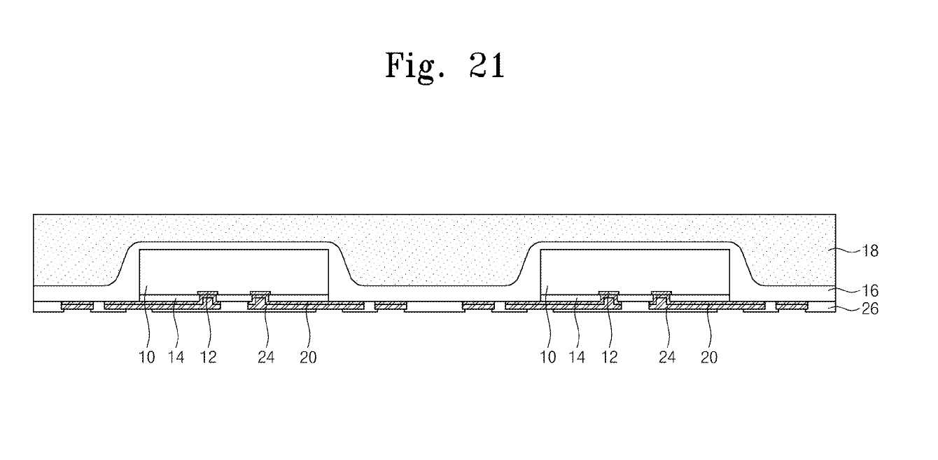

FIGS. 21 through 25 are cross-sectional views illustrating a method of forming a semiconductor package of FIG. 20 according to some embodiments. The second semiconductor package 104 may have substantially the same elements as the semiconductor package 100 of FIG. 1. Thus, a method of forming the second semiconductor package 104 may be substantially the same as the method of forming the semiconductor package 100. However, the shape of the first semiconductor package 103 may be different from that of the semiconductor package 100 of FIG. 1. Thus, a method of forming the first semiconductor package 103 will be described in detail.

Referring to FIG. 21, as described with reference to FIGS. 4 to 9 in the first embodiment, a first buffer layer 16 may be formed to cover a sidewall and/or a top surface of a first semiconductor chip 10. A first molding layer 18 is formed on the first buffer layer 16. A first seed layer pattern 20, a first redistribution pattern 24, and a second passivation layer 26 are formed on bottom surfaces of a first passivation layer 14 and the first buffer layer 16.

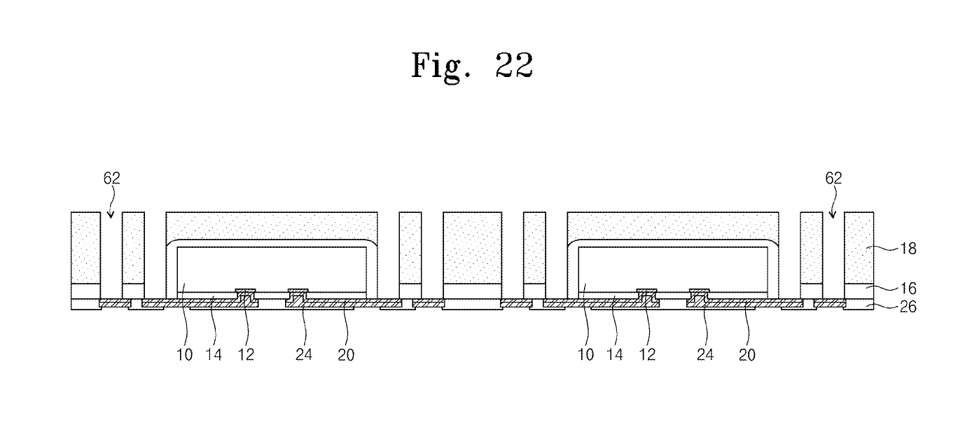

Referring to FIG. 22, the first molding layer 18 and the first buffer layer 16 may be partially removed to form through-holes 62 exposing portions of the first seed layer pattern 20. The process forming the through-hole 62 may use, for example, an etching process or a laser.

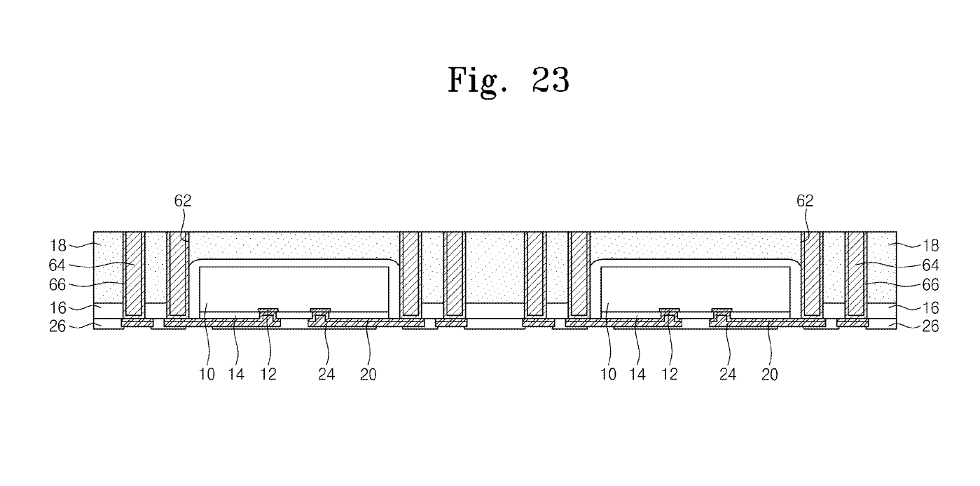

Referring to FIG. 23, according to some embodiments, a through-seed layer may be conformally formed on the first molding layer 18, in which the through-hole 62 is formed, and then a plating process may be performed to form a plating layer filling the through-hole 62. A planarization process may be performed on the plating layer to form a through-seed layer pattern 66 and a through-via 64 in the through-hole 62. At this time, the top surface of the first molding layer 18 may be exposed.

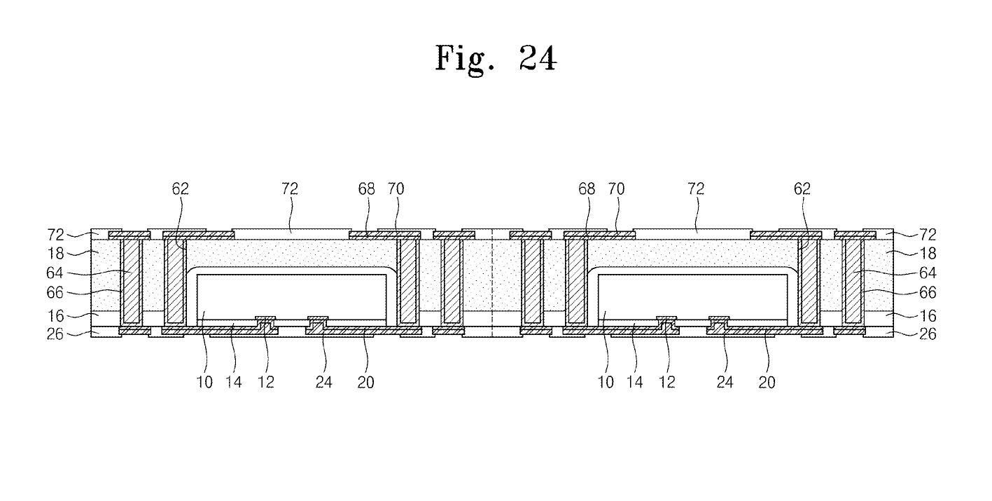

Referring to FIG. 24, a second seed layer pattern 68, a second redistribution pattern 70, and a third passivation layer 72 are formed on the top surface of the first molding layer 18 by the method described with reference to FIGS. 8 to 10 according to some embodiments. A first solder ball 28 may be bonded to the first redistribution pattern 24 which is not covered by the second passivation layer 26 so as to be exposed.

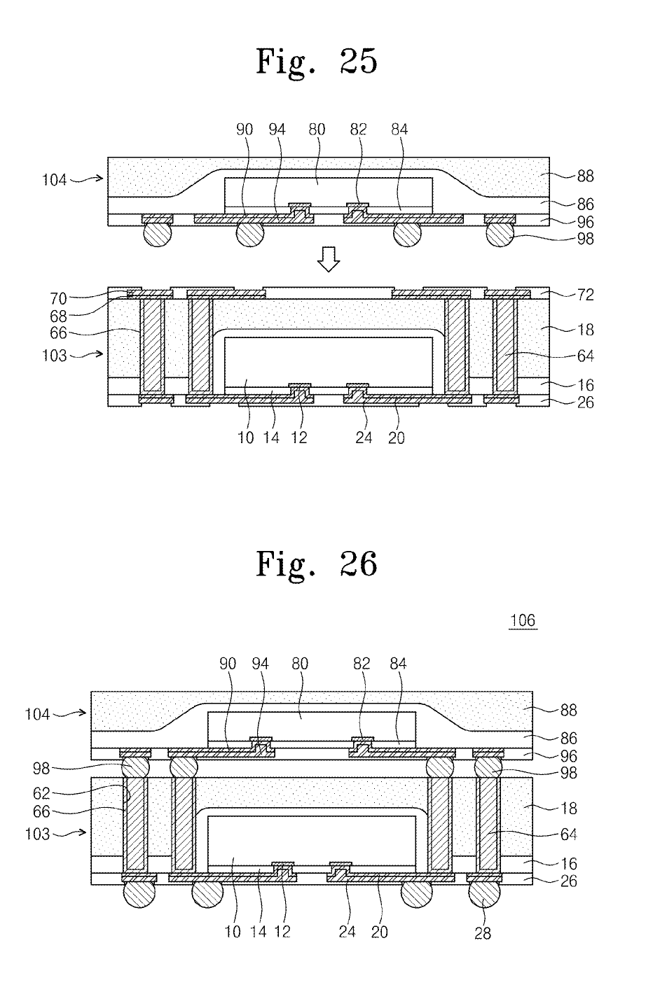

Referring to FIG. 25, a singulation process is performed to separate individual first semiconductor packages 103 from each other. After the first semiconductor package 103 is singulated, the second semiconductor package 104 may be mounted on the first semiconductor package 103.

The second semiconductor package 104 may be formed by the same method as the semiconductor package 100 of the first embodiment. The second semiconductor package 104 includes a second semiconductor chip 80. Second conductive pads 82 may be disposed at a bottom surface of the second semiconductor chip 80 and may be covered by a fourth passivation layer 84. A top surface and/or a sidewall of the second semiconductor chip 80 may be covered by a second buffer layer 86. A second molding layer 88 may be formed on the second buffer layer 86. Third redistribution patterns 94 are disposed adjacent a bottom surface of the fourth passivation layer 84 and a bottom surface of the second buffer layer 86. The third redistribution patterns 94 are electrically connected to the second conductive pads 82. A third seed layer pattern 90 may be disposed between the third redistribution pattern 94 and the second conductive pad 82, between the third redistribution pattern 94 and the fourth passivation layer 84, and between the third redistribution pattern 94 and the second buffer layer 86. A fifth passivation layer 96 covers portions of the third redistribution patterns 94 and portions of the second buffer layer 86 and the fourth passivation layer 84. A second solder ball 98 is adhered on an exposed portion of the third redistribution pattern 94 which is not covered by the fifth passivation layer 96.

Referring back to FIG. 20, when the second semiconductor package 104 is mounted on the first semiconductor package 103, the second solder ball 98 may be in contact with the second redistribution pattern 70. The second solder ball is then melted and attached to the second redistribution pattern 70. Thus, the semiconductor package 105 may be formed. Other elements of the semiconductor package 105 may be the same as or similar to the corresponding elements of the semiconductor package of the first embodiment.

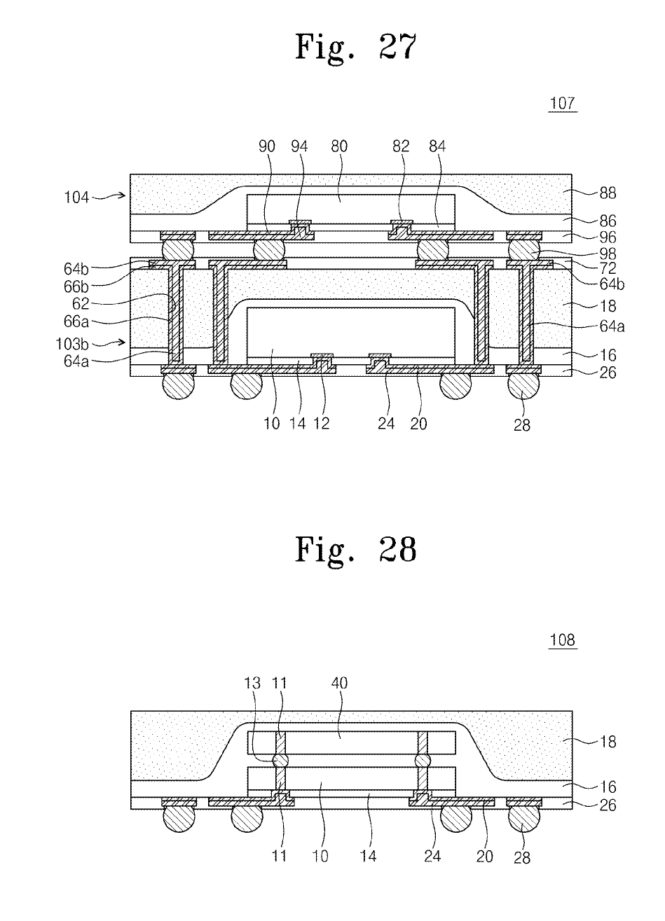

FIGS. 26 and 27 are cross-sectional views illustrating modified examples of a semiconductor package of FIG. 20.

Referring to FIG. 26, according to the present modified example, a semiconductor package 103a of a semiconductor package 106 does not include the second seed layer pattern 68, the second redistribution pattern 70, and the third passivation layer 72 of FIG. 20. In the semiconductor package 106, a second solder ball 98 may be directly in contact with a through-via 64, and a top surface of a first molding layer 18 may be exposed. Other elements of the semiconductor package 106 are the same as described with reference to FIG. 20.

Referring to FIG. 27, in a first semiconductor package 103b of a semiconductor package 107 according to the present modified example, a through-via 64a and a second redistribution pattern 64b may be connected to each other without a boundary therebetween. In other words, the through-via 64a and the second redistribution pattern 64b may form a single integral body. Additionally, a through-seed layer pattern 66a and a second seed layer pattern 66b may be connected to each other without a boundary therebetween. In other words, the through-seed layer pattern 66a and the second seed layer pattern 66b may also form a single integral body. A width of a through-hole 62 in the present modified example may be smaller than a width of the through-hole 62 illustrated in FIG. 22. Other elements of the semiconductor package 107 may be substantially the same as described with reference to FIG. 20. Some aspects of the present invention applied in one embodiment may also be embodied in another embodiment. For example, the through- seed layer pattern 66a may be formed using a soft-lithography technology. Also, the through-seed layer pattern 66a and the second redistribution pattern 64b may collectively form a redistribution layer. Such a redistribution layer may also be formed as a single layer.

According to a method of forming the first semiconductor package 103b of FIG. 27, the width of the through-hole 62 may be formed to be narrower, a seed layer may be formed, and then a plating process and an etching process may be performed to form the through-seed layer pattern 66a, the second seed layer pattern 66b, the through-via 64a, and the second redistribution pattern 64b simultaneously. At this time, the planarization process described with reference to FIG. 23 is not performed. And then subsequent processes described with reference to FIGS. 24 and 25 may be performed to form the semiconductor package 107.

### Fourth Embodiment

FIG. 28 is a cross-sectional view illustrating a semiconductor package according to a fourth embodiment of the inventive concept.

Referring to FIG. 28, in a semiconductor package 108 according to the present embodiment, a second semiconductor chip 40 is mounted on a first semiconductor chip 10. Each of the first and second semiconductor chips 10 and 40 may include a through-via 11 penetrating each of the first and second semiconductor chips 10 and 40. The second semiconductor chip 40 may be mounted on the first semiconductor chip 10, for example, by a flip chip bonding method through first external terminals such as first solder balls 13 disposed between the first and second semiconductor chips 10 and 20. The first solder ball 13 is electrically connected to the through-vias 11. A first passivation layer 14 may be disposed on a bottom surface of the first semiconductor chip 10. A buffer layer 16 covers top surfaces and sidewalls of the first and second semiconductor chips 10 and 40. A molding layer 18 is disposed on the buffer layer 16. Seed layer patterns 20, redistribution patterns 24, and a second passivation layer 26 are disposed on bottom surfaces of the first passivation layer 14 and the buffer layer 16. Second solder balls 28 are disposed bottom surfaces of the redistribution patterns 24.

In FIG. 28, the through-vias 11 may be directly in contact with the first solder balls 13. However, the inventive concept is not limited thereto. Redistribution patterns described with reference to FIG. 20 may additionally be disposed on the top surface of the first semiconductor chip 10 and the bottom surface of the second semiconductor chip 40, respectively. In this case, the first solder ball 13 may be in contact with the additional redistribution patterns.

Other elements and other processes of the semiconductor package 108 are the same as/similar to corresponding elements and corresponding processes described in the first to third embodiments.

The aforementioned semiconductor package technique may be applied to various kinds of semiconductor devices and package modules including them.

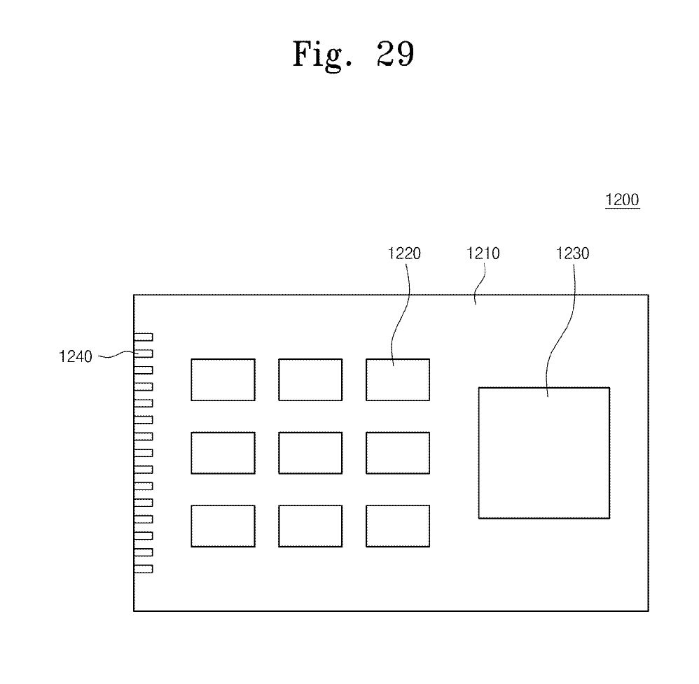

FIG. 29 is a schematic view illustrating an example of package modules including semiconductor packages according to some embodiments of the inventive concept. Referring to FIG. 29, a package module 1200 may include semiconductor devices 1220 and a semiconductor integrated circuit chip 1230 packaged in a QFP (quad flat package) package. The semiconductor devices 1220 and 1230 assembled with the semiconductor packaging techniques according to some embodiments of the inventive concept are installed on a substrate 1210, so that the package module 1200 may be formed. The package module 1200 may be connected to an external electronic device through an external connection terminal 1240 disposed at one side edge of the substrate 1210.

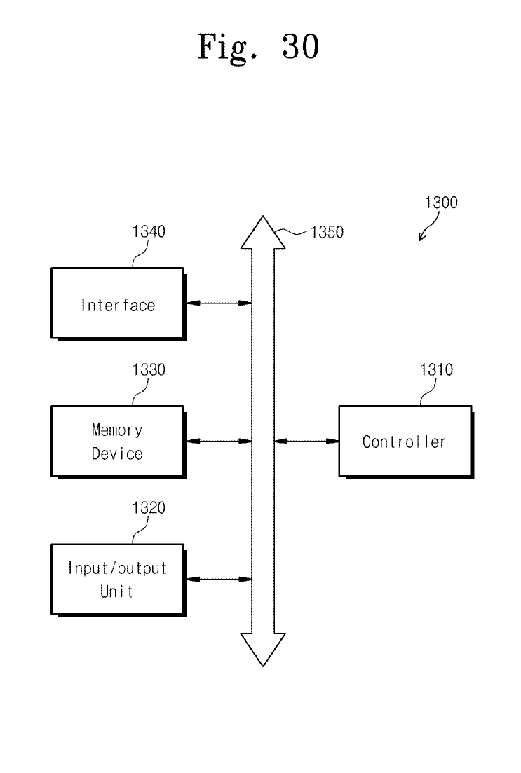

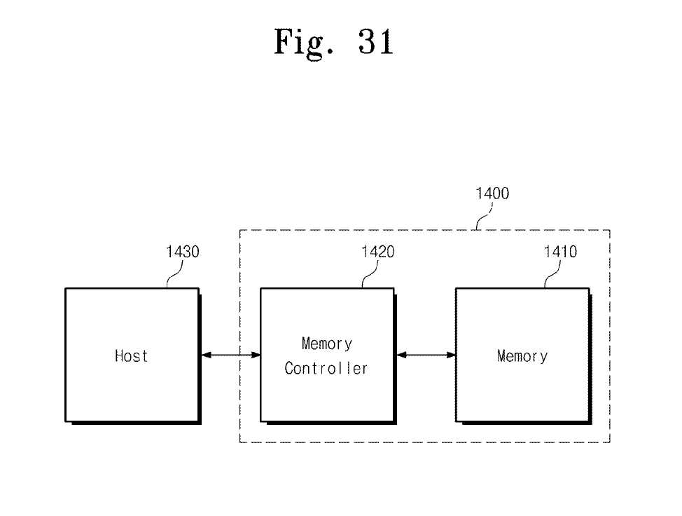

The semiconductor package technique described above may be employed to form an electronic system as shown in FIG. 30. FIG. 30 is a schematic block diagram illustrating an example of electronic systems including semiconductor packages formed according to some embodiments of the inventive concept.

Referring to FIG. 30, an electronic system 1300 may include a controller 1310, an input/output (I/O) unit 1320, and a memory device 1330. The controller 1310, the I/O unit 1320, and the memory device 1330 may be combined with each other through a data bus 1350. The data bus 1350 may correspond to a path through which electrical signals are transmitted. For example, the controller 1310 may include at least one of a microprocessor, a digital signal processor, a microcontroller or other logic devices. The other logic devices may have a similar function to any one of the microprocessor, the digital signal processor and the microcontroller. The controller 1310 and/or the memory device 1330 may be assembled in at least one of the semiconductor packages according to some embodiments of the inventive concept. The I/O unit 1320 may include a keypad, a keyboard and/or a display unit. The memory device 1330 may store data and/or commands executed by the controller 1310. The memory device 1310 may include a volatile memory device and/or a non-volatile memory device. In some embodiments, the memory device 1310 may be formed a flash memory device. The flash memory device may be realized as solid state disks (SSD). In this case, the electronic system 1300 may stably store mass data to the flash memory system. The electronic system 1300 may further include an interface 1340 that transmits electrical data to a communication network or receives electrical data from a communication network. The interface 1340 may operate by wireless or cable. For example, the interface 1340 may include an antenna for wireless communication or a transceiver for cable communication. Although not shown in the drawings, an application chipset and/or a camera image processor (CIS) may further be provided in the electronic system 1300.

The electronic system 1300 may be realized as a mobile system, a personal computer, an industrial computer, or a logic system performing various functions. For example, the mobile system may be one of a personal digital assistant (PDA), a portable computer, a web tablet, a wireless phone, a mobile phone, a laptop computer, a digital music system, and an information transmit/receive system. When the electronic system 1300 performs wireless communication, the electronic system 1330 may be used in a communication interface protocol such as a 3-generational communication system (e.g. CDMA, GSM, NADC, E-TDMA, WCDMA, CDMA 2000).

The semiconductor package technique described above may be employed in a memory system as shown in, for example, FIG. 31. FIG. 31 is a schematic block diagram illustrating an example of memory systems employing semiconductor packages according to some embodiments of the inventive concept.

Referring to FIG. 31, a memory system 1400 may include a non-volatile memory device 1410 and a memory controller 1420. The non-volatile memory device 1410 and the memory controller 1420 may store data or read stored data. The non-volatile memory device 1410 may include at least one of non-volatile memory devices applied with the semiconductor package technique according to some embodiments. The memory controller 1420 may control the non-volatile memory device 1410 in order to read the stored data and/or to store data in response to read/write request of a host.

According to some embodiments of the inventive concept, the semiconductor package may include a buffer layer disposed between at least one sidewall of the semiconductor chip and the molding layer. The buffer layer may have a property, e.g., a physical property, different from those of the molding layer and the semiconductor chip. During the method of forming the semiconductor package, the stress may be caused between the molding layer and the semiconductor chip due to the difference between the properties of the molding layer and semiconductor chip. Thus, a space between the molding layer and the semiconductor chip may widen or the semiconductor package may be warped. Additionally, board level reliability may be deteriorated by the warpage of the semiconductor package, so that a joint crack may occur at the solder ball bonded to a board substrate. However, according to embodiments of the inventive concept, the buffer layer may relieve the stress caused by the difference between the physical properties of the semiconductor chip and the molding layer. Thus, it is possible to resolve the problems caused by the stress. As a result, the reliability of the semiconductor package may be improved by the buffer layer.

According to other embodiments of the inventive concept, the semiconductor package does not include a printed circuit board, so that the total thickness of the semiconductor package may be reduced.

According to still other embodiments of the inventive concept, since the buffer layer extends to cover the sidewall of the semiconductor chip, the redistribution pattern may also be formed on the bottom surface of the buffer layer and the solder ball may be adhered on the redistribution pattern under the buffer layer. Thus, it is easy to bond the solder balls suitably for an international standard. Additionally, the semiconductor package may be easily handled and tested.

Furthermore, in the method of forming the semiconductor package according to some embodiments of the inventive concept, after the buffer layer is formed to cover at least one sidewall of the semiconductor chip, the molding layer is formed. If the molding layer is directly formed on the semiconductor chip without the formation of the buffer layer, the molding layer may encroach upon the bottom surface of the semiconductor chip by a strong pressure during the process forming the molding layer. Thus, the conductive pad may be contaminated, the conductive pad may be covered by the molding layer, or it may be possible to cause a so-called swimming problem such that an entire semiconductor chip is surrounded by the molding layer. Moreover, the semiconductor chip may be distorted or rotated by flowing of the molding layer solution during the process forming the molding layer. However, according to some embodiments of the inventive concept, the molding layer is formed after the buffer layer is formed. Thus, the molding layer does not encroach upon the bottom surface of the semiconductor chip or the passivation covering the bottom surface of semiconductor chip). Additionally, it is possible to reduce or prevent the swimming problem and/or the rotation problem. As a result, the reliability of the semiconductor package may be improved.

On the other hand, in a method of forming a fan-out wafer level package, a molding layer may be formed after a semiconductor chip is fixed on a carrier, for example, by an adhesion layer. However, for reducing the swimming and/or rotation problem of the semiconductor chip, the process forming the molding layer may be performed after a portion of the semiconductor chip may be pressed into the adhesion layer by a predetermined depth. Thus, a height difference may occur between bottom surfaces of the molding layer and the semiconductor chip (or the passivation covering the bottom surface of the semiconductor chip) in the completed fan-out wafer level package. It may be difficult to form the redistribution pattern directly on the package due to the height difference. Thus, an additional insulating layer on the bottom surfaces of the semiconductor chip and the mold may be required for reducing the height difference. The insulating layer may cover the conductive pads, so that an additional patterning process including an etching process and a photolithography process may also be required for opening the conductive pads covered by the insulating layer. Thus, the formation processes of the package may be complicated and process cost may increase. However, according to some embodiments of the inventive concept, the buffer layer covering the semiconductor chip may be performed under the atmospheric pressure, so that the swimming and/or rotation problems may not occur. Thus, it is possible to reduce or prevent the height difference between bottom surfaces of the buffer layer and the semiconductor chip (or the passivation covering the bottom surface of the semiconductor chip). As a result, the redistribution pattern may be easily and directly formed, so that the processes may be simplified and the manufacturing costs may be reduced.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Various operations will be described as multiple discrete steps performed in a manner that is most helpful in understanding the invention. However, the order in which the steps are described does not imply that the operations are order-dependent or that the order that steps are performed must be the order in which the steps are presented.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1-34. (canceled)

35. A method of forming a semiconductor package, the method comprising:
placing a first semiconductor chip including a first conductive pattern on a carrier;
forming a buffer layer covering a top surface and a sidewall of the first semiconductor chip;
forming a molding layer on the buffer layer;
separating the first semiconductor chip from the carrier; and
forming a first redistribution layer electrically connected to the first conductive pattern on a bottom surface of the first semiconductor chip.

36. The method of claim 35, wherein forming the buffer layer comprises:
coating the buffer layer on the first semiconductor chip.

37. The method of claim 36, further comprising:
removing a portion of the buffer layer on the first semiconductor chip to expose a top surface of the first semiconductor chip.

38. The method of claim 35, further comprising:
placing a second semiconductor chip including a second conductive pattern not overlapping the first semiconductor chip on the first semiconductor chip before forming the buffer layer; and
patterning the buffer layer to form a hole exposing the second conductive pattern before forming the first redistribution layer,
wherein the first redistribution layer fills the hole.

39. The method of claim 35, further comprising:
mounting a second semiconductor chip on the first semiconductor chip before forming the buffer layer,
wherein the buffer layer extends to cover at least one sidewall of the second semiconductor chip.

40. The method of claim 35, further comprising:
patterning the molding layer and the buffer layer to form a hole exposing the first redistribution layer; and
forming a through-via within the hole.

41. The method of claim 40, further comprising:
forming a second redistribution layer electrically connected to the through-via on the molding layer.

42. The method of claim 40, further comprising:
mounting an upper semiconductor package electrically connected to the through-via.

43. The method of claim 35, further comprising:
removing a portion of the buffer layer on the first semiconductor chip to expose a top surface of the first semiconductor chip.

44. A method of forming a semiconductor package, comprising:
placing a plurality of semiconductor chips each including a passivation layer having an opening to expose a bonding pad on a carrier;
coating the plurality of semiconductor chips with a buffer layer such that substantially all of sidewalls of the plurality of semiconductor chips are covered with the buffer layer;
forming a molding layer overlying the buffer layer; and
forming a redistribution layer electrically connected to the bonding pad of a corresponding one of the plurality of semiconductor chips.

45. The method of claim 44, wherein the redistribution layer is in direct contact with the passivation layer and the buffer layer.

46. The method of claim 44, wherein coating the plurality of semiconductor chips comprises coating a backside of the plurality of semiconductor chip and the sidewalls of the plurality of semiconductor chips.
